(19) United States
(12) Patent Application Publication
(10) Pub. No.: US 2023/0155010 A1
(43) Pub. Date: May 18, 2023

(54) MANAGING SEMICONDUCTOR LAYERS FOR A BIPOLAR-JUNCTION TRANSISTOR IN A PHOTONIC PLATFORM

(71) Applicant: Ciena Corporation, Hanover, MD (US)

(72) Inventor: Antoine Bois, Quebec (CA)

(73) Assignee: Ciena Corporation, Hanover, MD (US)

(21) Appl. No.: 17/524,908

(22) Filed: Nov. 12, 2021

(51) Int. Cl. H01L 29/73; H01L 29/10; H01L 29/08; H01L 29/66

(52) U.S. Cl. CPC H01L 29/7302; H01L 29/1004; H01L 29/0804; H01L 29/0821; H01L 29/66234

(57) ABSTRACT

An article of manufacture, having a semiconductor layer and a dielectric layer. The semiconductor layer comprising a first surface and a second surface. The dielectric layer located adjacent to the first surface of the semiconductor layer. One or more base portions of the semiconductor in direct contact with and extending from the dielectric layer. One or more collector portions of the semiconductor in direct contact with and extending from the dielectric layer. One or more emitter portions of the semiconductor in direct contact with and extending from the dielectric layer. The one or more collector portions are spaced apart from the one or more emitter portions by the one or more base portions.

### TECHNICAL FIELD

This disclosure relates article of manufacture and method of forming the article of manufacture where the article of manufacture is a bipolar-junction transistor having a photonic platform and including one or more base portions, one or more collector portions, and one or more emitter portions that are all in contact with a dielectric, a semiconductor, or both that form a substrate.

### BACKGROUND

Photonic integrated circuits (PICs) often include optical waveguides for transporting optical waves around a device and into and out of various photonic structures. A waveguide is a structure that confines and guides the propagation of an electromagnetic wave. Some electromagnetic waves have a spectrum that has a peak wavelength that falls in a particular range of optical wavelengths (e.g., between about 100 nm to about 1 mm, or some subrange thereof), also referred to as “optical waves,” “light waves,” or simply “light,” and waveguides for light will be referred to herein as “optical waveguides.” These optical waveguides may be implemented, for example, by forming a core structure from a material having a higher refractive index (e.g., silicon, or silicon nitride) surrounded by a cladding (also called a “buffer”) comprising one or more materials (or air) that have a lower refractive index. For example, the core structure may be formed by the silicon layer over a buried oxide (BOX) layer (e.g., silicon dioxide) of a substrate, such as a silicon-on-insulator (SOI) wafer, while the cladding would be formed by the oxide of the BOX layer and the silicon dioxide deposited on top of the core structure.

### SUMMARY

In one aspect, in general, an article of manufacture, having a semiconductor layer and a dielectric layer. The semiconductor layer comprising a first surface and a second surface. The dielectric layer located adjacent to the first surface of the semiconductor layer. One or more base portions of the semiconductor in direct contact with and extending from the dielectric layer. One or more collector portions of the semiconductor in direct contact with and extending from the dielectric layer. One or more emitter portions of the semiconductor in direct contact with and extending from the dielectric layer. The one or more collector portions are spaced apart from the one or more emitter portions by the one or more base portions.

In another aspect, in general, a method including etching, doping, and forming. Etching and doping all or a portion of a semiconductor layer to form an emitter portion directly on a dielectric layer. Etching and doping all or a portion of the semiconductor layer to form a base portion directly on the dielectric layer. Etching and doping all or a portion of the semiconductor layer to form a collector portion directly on the dielectric layer, wherein the collector portion and the emitter portion are separated by the base portion. Forming a first metal contact structure within a via pattern in the dielectric layer to form an emitter contact directly on the semiconductor. Forming a first metal contact structure within a via pattern in the dielectric layer to form a base contact directly on the semiconductor. Forming a first metal contact structure within a via pattern in the dielectric layer to form a collector contact directly on the semiconductor.

Aspects can have one or more of the following advantages.

Typical photonic platforms, such as CMOS-compatible SOI platform includes electronic devices such as photodetectors, but are not typically used for certain kinds of electronic devices such as bipolar junction transistors (BJTs). In some cases, BJTs are built layer by layer on a substrate such that one layer is stacked upon another layer. But, it may be advantageous to instead build BJT portions extending from a common dielectric layer, such as a BOX layer in an SOI platform. Implementations of various techniques described herein enable BJTs to be integrated into a photonics platform, such as a CMOS-compatible SOI platform, with certain advantageous characteristics. For example, it may be desirable to have a BJT that has a small base surface area, an emitter portion with limited contact with the base, and/or a BJT with a low series resistance.

Other features and advantages will become apparent from the following description, and from the figures and claims.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1A is a top view of transistor with a 45-degree shape.

FIG. 1B is a top view of a transistor with a Manhattan shape.

FIG. 1C is a top view of a transistor with a curvilinear shape.

FIG. 1D is a cross-sectional view of FIG. 1C along line ID-ID.

FIG. 2 illustrates a characteristic curve of the transistor taught herein.

FIG. 3 illustrates a characteristic curve of the transistor taught herein.

FIG. 4 illustrates a characteristic curve of the transistor taught herein.

FIG. 5 illustrates a characteristic curve of the transistor taught herein.

### DETAILED DESCRIPTION

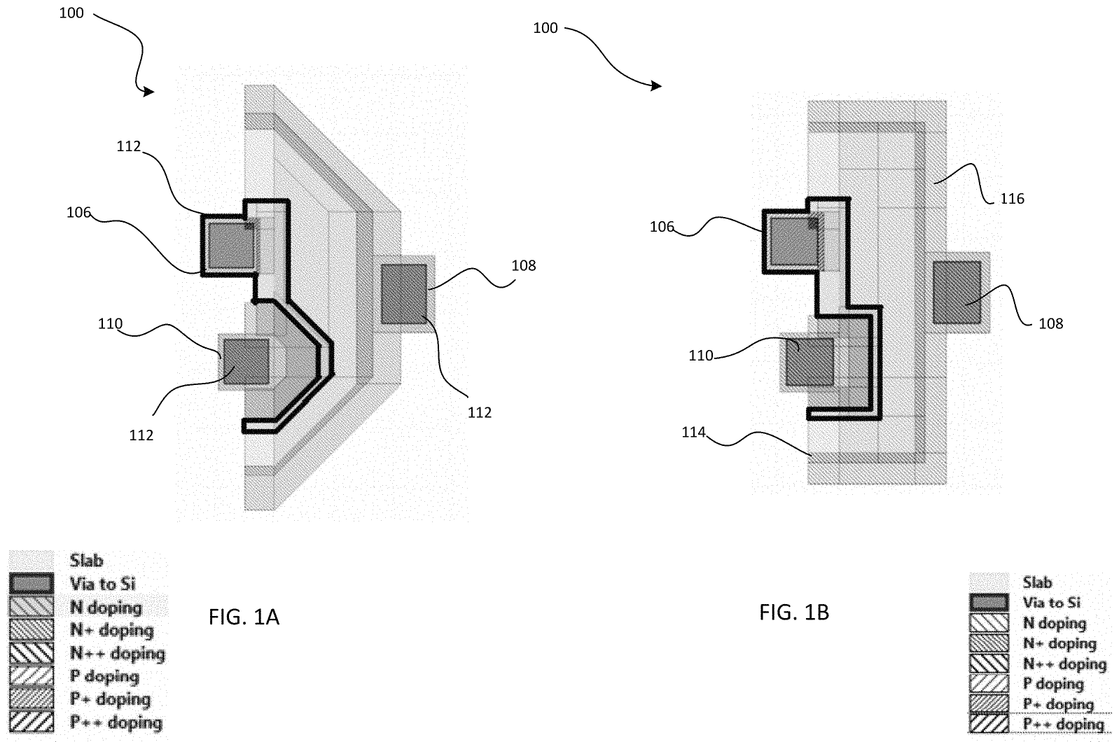

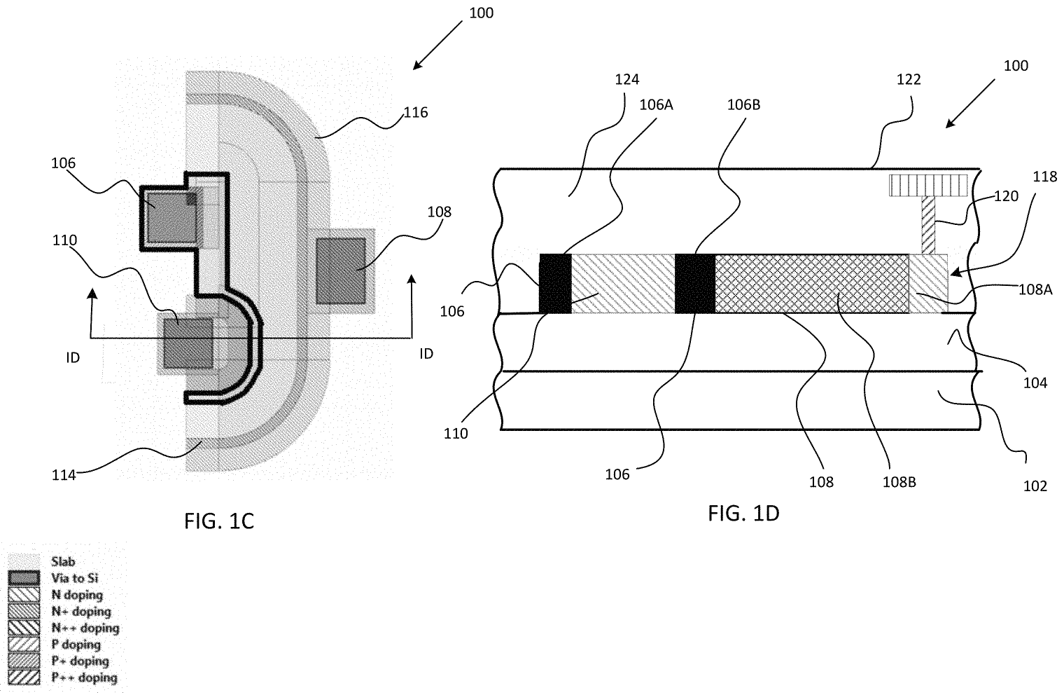

FIG. 1A illustrates a top view of an article of manufacture 100 (hereinafter AOM) 100 (e.g., a transistor, bipolar junction transistor (BJT)). The AOM 100 may function as a transistor, a switch, a photonic integrated circuit element, a photonic device, a transistor, a BJT, a unijunction transistor (UJT), a negative differential resistance (NDR), or a combination thereof. The AOM 100 may be integrated into a larger device and assist in that device in operating. The AOM 100 is shown as have a 45-degree shape. The AOM 100 includes a base portion 106, a collector portion 108, and an emitter portion 110. Each of the base portion 106, collector portion 108, and the emitter portion 110 include a conductive (e.g., metal) contact structure 112 that can be used to form electrical connections to other portions of a system fabricated on the same integrated circuit. In some implementations, the integrated circuit includes photonic integrated circuit elements including optical guiding structures such as optical waveguides and optical mode converters. For example, in a silicon-on-insulator (SOI) wafer there may be waveguides formed in the same silicon layer in which the AOM 100 is formed, which can be configured to include a guiding core that is formed between cladding layers above and below the guiding core, such as a BOX layer below and a deposited oxide layer above. The techniques described herein enable photonic circuit elements and devices to be closely integrated with electronic devices such as BJTs using a common fabrication platform and fabrication processes.

The base portion 106 mediates flow between the emitter portion 110 and the collector portion 108. The base portion 106 is located between the emitter portion 110 and the collector portion 108. The base portion 106 may extend orthogonal to a substrate (e.g., a semiconductor or a dielectric). The base portion 106 may extend in a direction parallel to the emitter portion 110 and the collector portion 108. The base portion 106, collector portion 108, and emitter portion 110 may all be in communication with a common substrate (not shown). The base portion 106 may include metal. The base portion 106 may be doped. The base portion 106 may have a different doping, a lower doping, an opposite doping, or a combination thereof than the collector portion 108, the emitter portion 110, or both. The base portion 106 may be a p-type. The base portion 106 may be positively doped. The base portion 106 may be a n-type. The base portion 106 may be negatively doped. The base portion 106 may have a doping strength such that the doping strength may be a p-type, Pp-type (also known as P+), Ppp-type (also known as P++) doping, or a combination thereof (NPN type), or may be a n-type, Np-type (also known as N+), Npp-type (also known as P++) doping, or a combination thereof (PNP type). The base portion 106 may be doped more than the collector portion 108. The base portion may be doped less than the emitter portion 110. The base portion 106 may allow current to extend from the emitter portion 110 to the collector portion 108. The base portion 108 may be thinner than the collector portion 108 and the emitter portion 110.

The collector portion 108 may collect electrons or collect holes (e.g., a reverse flow of electrons causes mobile holes to be formed). The collector portion 108 functions to receive holes, electrons, or both from the emitter portion 110. The collector portion 108 may be the least doped portion (e.g., doped less than the base portion 106 and the emitter portion 110). The collector portion 108 may be positively doped. The collector portion 108 may be a p-type. The collector portion 108 may be a n-type. The doping strength may be varied such as Np-type (also known as N⁺) or Npp-type (also known as N⁺⁺). The collector portion 108 and the emitter portion 110 may be doped the same way. The collector portion 108, the emitter portion 110, or both may be doped opposite the base portion 106.

The emitter portion 110 may emit electrons or holes. The emitter portion 110 may pass electrons or holes through the base portion 108 into the collector portion 106. The emitter portion 110 may be the highest doped portion. The emitter portion 110 may be positively doped. The emitter portion 110 may be a p-type, Pp-type, Ppp-type, or a combination thereof. The emitter portion 110 may be negatively doped. The emitter portion 110 may be a n-type, Np-type, Npp-type, or a combination thereof. The collector portion 108 and the emitter portion 110 may be doped the same way. The collector portion 108, the emitter portion 110, or both may be doped opposite the base portion 106.

Doping a material such as silicon can be accomplished as part of a fabrication process by introducing atoms of a foreign material (also called “impurities”), which can be of two different types: a n-type dopant (which provides free electrons as negative charge carriers (e.g., donor)), or a p-type dopant (which provides mobile holes as positive charge carriers (e.g., acceptor)). Examples of p-type dopants include boron, gallium, or aluminum. Examples of n-type dopants include arsenic, phosphorous, or antimony. The concentration of a dopant can be characterized by different degrees of concentration, which can be associated with corresponding symbols (P for p-type, and N for n-type) within various quantitative ranges. A “P” or “N” designation of concentration is a moderate degree of doping (e.g., a concentration of less than 1018 atoms per cubic centimeter). A doping strength of “P+” or “N+” designation of concentration (also referred to herein as “Pp” or “Np”) is a heavy degree of doping (e.g., a concentration of between about 1018 to 1020 atoms per cubic centimeter). A “P++” or “N++” designation of doping strength or doping concentration (also referred to herein as “Ppp” or “Npp”) is an even heavier degree of doping (e.g., a concentration of greater than about 1020 atoms per cubic centimeter). Dopant concentration may vary vertically across a cross-section according to implantation energy.

An area under metal contact structure 112 may be partially doped such that a portion is doped to form a contact to facilitate an electrical connection. The doping that is adjacent and under the metal contact structure 112 may form an ohmic contact. The area under the contacts may be fully doped to facilitate a flow of electrons. An amount of doping adjacent the metal contact structure 112 may vary an amount of resistance. The metal contact structure 112 may be connected to a circuit or may connect the AOM 100 within a circuit.

FIG. 1B illustrates a top view of an AOM 100 having a manhattan shape. The AOM 100 includes a base portion 106, a collector portion 108, and an emitter portion 110. The AOM 100 may be doped and constructed in a same manner as the AOM of FIG. 1A. The manhattan shape is substantially rectangular in shape. The base portion 106 and the collector portion 108 extend out of a first side 114 and the collector portion 108 extend out of a second side 116.

FIG. 1C illustrates a top of an AOM 100 having a curvilinear shape. The AOM 100 includes a base portion 106, a collector portion 108, and an emitter portion 110. The AOM 100 may be doped and constructed in a same manner as the AOM 100 of FIG. 1A. The curvilinear shape may have one flat side and one curved side. The AOM 100 may have a substantially “D” shape. The AOM 100 may have a base portion 106 and an emitter portion 110 extending out of a first side 114. The base portion 106 and the emitter portion 110 may extend out of the flat side. The collector portion 108 may extend out of a second side 116 (with the second side being directly opposite the first side 114). The collector portion 108 may extend out of the curved side of the AOM 100.

FIG. 1D is a cross-sectional view of the AOM 100 of FIG. 1C along line ID-ID. The AOM 100 includes a semiconductor 102 that forms the substrate for the AOM 100. The AOM 100 has a dielectric 104 located on the semiconductor 102. The semiconductor 102 may be any material that provides some conductivity and some insulation. The semiconductor 102 may be made of or include silicon, germanium, gallium arsenide, indium antimonide, cadmium selenide, or a combination thereof. The semiconductor may be a single layer.

The dielectric 104 may be any material that has high capacitance, prevents electrical leakage, insulates the semiconductor, or a combination thereof. The dielectric 104 may have a thermal conductivity of about 5 W/(m*K) or less, about 3 W/(m*K) or less, about 1.5 W/(m*K) or less (e.g., about 1.4 W/(m*K)). The dielectric 104 may be or include silicon, silicone dioxide, porcelain, mica, glass, or a combination thereof. The dielectric 104 may be a buried oxide layer (BOX). The dielectric 104 may be a continuous layer. The semiconductor 102 may include metallization on top of it or may be etched. The metallization may be formed after oxide 124 is deposited, by patterning a via in such a layer and filling it with metal.

The dielectric 104 may separate the semiconductor 106 from the semiconductor 102. The dielectric 104 may be free of extending between the any of the base portion 106, the collector portion 108, and the emitter portion 110.

A metal contact structure 120 and metal contact layer 122 may be located within the oxide 124 above the semiconductor 102 and be in electrical contact with the base portion 106, the collector portion 108, or the emitter portion 110. The metal contact structures 112 may be configured to include metal layer 122 and vias 120 that form an electrical connection to portions of the AOM 100 (although only one surface contact and via structure is being shown for clarity of the figure). The metal contact structures 112, including the vias 120, all or a portion of the metal layer 122, or a combination thereof may be located within oxide 124. The metal contact structures may be located above the dielectric 104, on an oxide layer 124, or both. The metal contract structures may be free of contact with the semiconductor 102. The metal contract structures may be located in a via pattern of an oxide.

The semiconductor 118 (e.g., doped semiconductor 118), a region surrounding the metal contact structures, or both are doped forming the base portion 106, the collector portion 108, and the emitter portion 110. Semiconductor 118 may be etched to a specific height from an unprocessed SOI wafer containing semiconductor 102, dielectric 104, and semiconductor 118. The base portion 106, the collector portion 108, and the emitter portion 110 may be etched at different depths. Each of the base portion 106, the collector portion 108, and the emitter portion 110 are directly in contact with and extend away from the dielectric 104. As shown, the base portion 106, the collector portion 108, and the emitter portion 110 all extend generally parallel to one another. The base portion 106, the collector portion 108, and the emitter portion 110 all connect to a same substrate (e.g., the dielectric 104, itself on top of semiconductor 102). The collector portion 108 may be free of the emitter portion 110, the base portion 106, or both extending over all or a portion thereof. For example, an upper most surface, a bottom most surface, or both of the emitter portion 110, the collector portion 108, the base portion 106, or a combination thereof may be free of any overlap by another portion.

The base portion 106, the collector portion 108, and the emitter portion 110 may all be sandwiched together. The base portion 106, the collector portion 108, and the emitter portion 110 all may be formed in parallel, in series, or both. As shown, when viewing FIG. 1C along lines ID-ID a portion of the base portion 106 is obscured by the emitter portion 110 so that the base portion 106 has first portion 106A and a second portion 106B visible on opposing sides of the emitter portion 110. Similarly, the collector portion 108 is shown with a main portion 108A and a second portion 108B that extends from a side of the AOM 100. A doping depth of the base portion 106, the collector portion 108, and the emitter portion 110 may be the same as shown. The doping depths may vary. The base portion 106 may have the largest doping depth. The collector portion 108 may have the largest doping depth. The emitter portion 110 may have the largest doping depth. The base portion 106 may have the smallest doping depth. The collector portion 108 may have the smallest doping depth. The emitter portion 110 may have the smallest doping depth.

The base portion 106, the collector portion 108, the emitter portion 110, or a combination thereof may be in direct communication with a via 120 (e.g., formed from a conductive material, such as metal). The via 120 may create an electrical connection with a metal layer 122 so that current may exit or enter the article of manufacture. An oxide 124 may extend over all or a portion of the base portion 106, the collector portion 108, the emitter portion 110, the vias 120, the surface contacts 122, or a combination thereof. The oxide 124 may encapsulate one or more of the layers discussed herein. The oxide layer may be an undoped silicate glass (USG).

The cross-sectional view of FIG. 1D is not drawn to scale in an attempt to clarify locations of the doped portions and surrounding structures. For clarity purposes only one via 120 and the metal layer 122 are shown to illustrate the relationship between the via 120 and the related portions. Moreover, the depths of the various components are not readily visible in the cross-section; however, FIG. 1C should be viewed in conjunction with FIG. 1D.

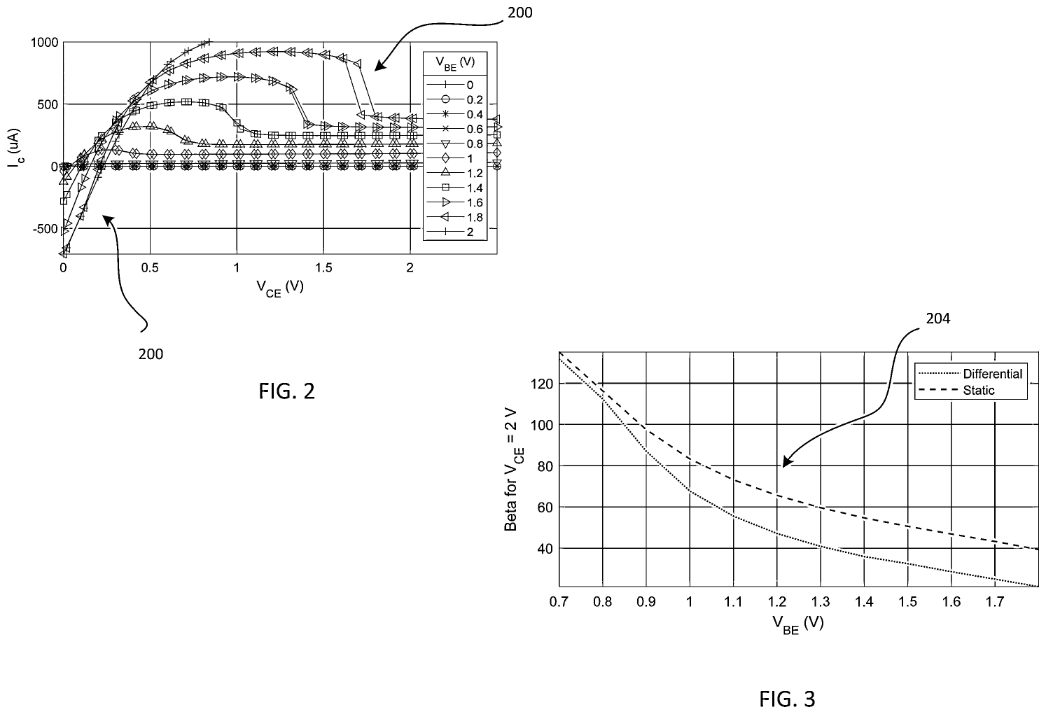

FIG. 2 illustrates a characteristic curve of the AOM taught herein. The characteristic curve illustrates the curve extending into the negative 200 because the base-collector junction is more strongly forward biased than the base-emitter junction. The AOM also exhibits overshoot with hysteresis 202 due to conductivity modulation from the base-collector junction being initially forward biased, reducing the resistance between the base and emitter and helping forward bias it, until the base-collector is eventually reverse-biased enough for current to decrease sufficiently and for resistance to increase sharply.

FIG. 3 illustrates a characteristic curve of the AOM relative to gain 204. The gain 204 falls due to a series resistance of the AOM in the absence of conductivity modulation and from high carrier injection.

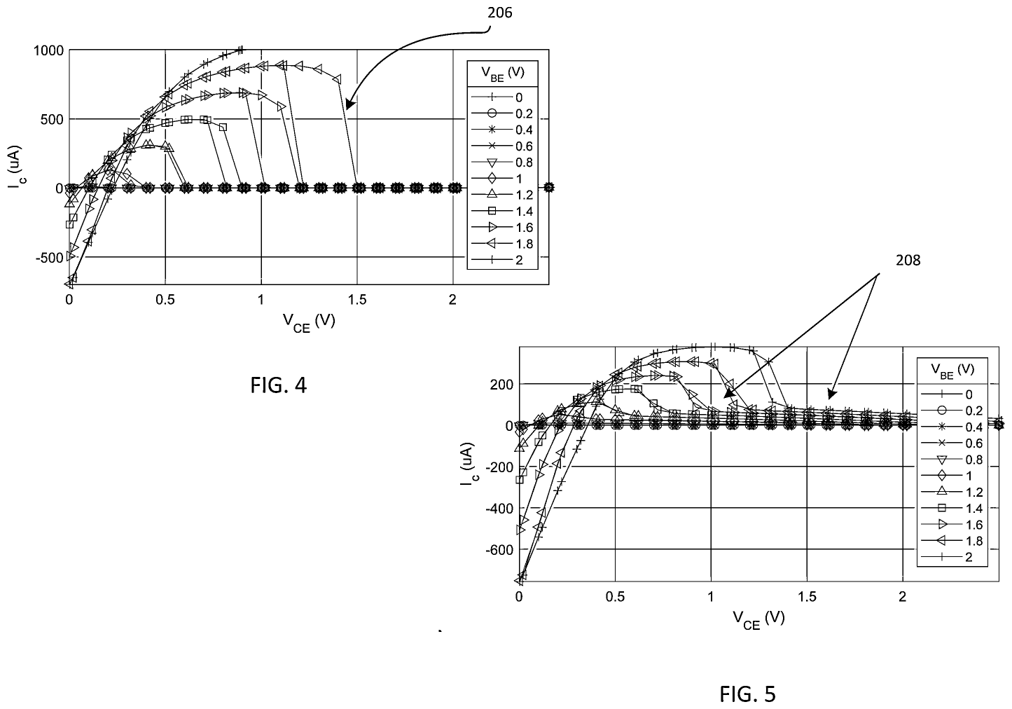

FIG. 4 illustrates a characteristic curve where the transistor effect has a breakdown. The base collector junction reaching a state of reverse bias reduces the amount of conductivity modulation thus preventing the base emitter junction from being forward biased, shutting the AOM off 206. This can act as a switch.

FIG. 5 illustrates a characteristic curve of an AOM including tunable regions 208. The negative differential resistance is tunable in the tunable region 208. The functionality is similar to that of a tunable unijunction transistor (UJT).

The present AOM may be created by a method of manufacture. The semiconductor may be formed. The semiconductor may be etched. The method of manufacture may include depositing a dielectric on the semiconductor. Forming via patterns in the dielectric by removing portions of the dielectric, selectively etching the dielectric, masking the semiconductor so that dielectric is applied to the mask and when the mask is removed the semiconductor is exposed, or a combination thereof. Metal may be placed in the via patterns to form the vias making contact to the doped semiconductor portions at one end of the via. Each via hole may receive one metal via with a metal layer formed at the other end of the via. Three via patterns may be formed, filled with a metal material, and three metal contacts may be formed on a top surface and connected to base, collector, and emitter portions of the AOM 100 by the metal vias. The semiconductor structures connected to the vias and forming the base, collector, and emitter portions may be doped. The doping selected may determine what portion is formed. The doping may form an emitter portion, a collector portion, and a base portion. The doping or doping strength may make a portion positive, negative, neutral, a free electron receptor, a free electron donor, or a combination thereof.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. An article of manufacture, comprising:
a semiconductor layer;
a dielectric layer in contact with the semiconductor layer;
one or more base portions of the semiconductor in direct contact with and extending from the dielectric layer;
one or more collector portions of the semiconductor in direct contact with and extending from the dielectric layer; and
one or more emitter portions of the semiconductor in direct contact with and extending from the dielectric layer;
wherein the one or more collector portions are spaced apart from the one or more emitter portions by the one or more base portions.

2. The article of manufacture of claim 1, wherein the dielectric layer comprises silicon dioxide or is a buried oxide layer.

3. The article of manufacture of claim 1, wherein the article of manufacture has a shape that is curvilinear, Manhattan, or 45-degrees.

4. The article of manufacture of claim 1, wherein the semiconductor layer is a single layer of silicon.

5. The article of manufacture of claim 1, wherein the article of manufacture is a bipolar junction transistor.

6. The article of manufacture of claim 1, wherein the article of manufacture exhibits conductivity modulation.

7. The article of manufacture of claim 1, wherein the emitter portion, the base portion, and the collector portion are based upon a doping and the emitter is doped with a N-type dopant, the base is doped with a P-type dopant, and the collector is doped with a N-type dopant.

8. The article of manufacture of claim 1, wherein the emitter portion, the base portion, and the collector portion are based upon a doping and the emitter is doped with a P-type dopant, the base is doped with a N-type dopant, and the collector is doped with a P-type dopant.

9. The article of manufacture of claim 1, wherein the base portion has a width that is less than the collector portion and the emitter portion.

10. The article of manufacture of claim 1, wherein the base portion, the emitter portion, the collector portion, or a combination thereof coexist in a semiconductor layer in a substantially parallel direction.

11. A method comprising:
etching and doping all or a portion of a semiconductor layer to form an emitter portion directly on a dielectric layer; and
etching and doping all or a portion of the semiconductor layer to form a base portion directly on the dielectric layer; and
etching and doping all or a portion of the semiconductor layer to form a collector portion directly on the dielectric layer, wherein the collector portion and the emitter portion are separated by the base portion;
forming a first metal contact structure within a via pattern in the dielectric layer to form an emitter contact directly on the semiconductor; and
forming a second metal contact structure within a via pattern in the dielectric layer to form a base contact directly on the semiconductor; and
forming a third metal contact structure within a via pattern in the dielectric layer to form a collector contact directly on the semiconductor.

12. The method of claim 11, wherein the emitter portion, the base portion, and the collector portion all coexist on the dielectric layer in a direction substantially parallel to one another.

13. The method of claim 11, further comprising doping the emitter portion with a N-type dopant, the base portion with a P-type dopant, and the collector portion with a N-type dopant.

14. The method of claim 11, further comprising doping the emitter portion with a P-type dopant, the base portion with a N-type dopant, and the collector portion with a P-type dopant.

15. The method of claim 11, wherein the semiconductor is a single layer of silicon.

16. The method of claim 11, further comprising shaping the semiconductor to have a shape that is curvilinear, Manhattan, or 45-degree.

17. The method of claim 11, wherein the method forms a bipolar junction transistor.

18. The method of claim 11, wherein the base portion has a width that is less than the collector portion and the emitter portion.

19. The method of claim 11, wherein the via pattern receiving the first metal contact is a first via, the via pattern receiving the second metal contact is a second via, and the via pattern receiving the third metal contact is a third via.

20. The method of claim 11, further comprising depositing an oxide over the semiconductor so that the deposited oxide encapsulates the semiconductor layer and the first metal contact, the second metal contact, and the third metal contact.
